(19) United States
(12) Patent Application Publication
(10) Pub. No.: US 2015/0240358 A1
(43) Pub. Date: Aug. 27, 2015

(54) SUSCEPTOR AND CHEMICAL VAPOR DEPOSITION APPARATUS HAVING THE SAME

(71) Applicant: SAMSUNG ELECTRONICS CO., LTD., Suwon-si (KR)

(72) Inventors: Nam Sung KIM, Suwon-si (KR); Jong Won JANG, Suwon-si (KR); Sung Min CHOI, Suwon-si (KR); Sang Heon HAN, Suwon-si (KR); Suk Ho YOON, Seoul (KR); Jeong Wook LEE, Yongin-si (KR)

(73) Assignee: SAMSUNG ELECTRONICS CO., LTD., Suwon-si (KR)

(21) Appl. No.: 14/506,182

(22) Filed: Oct. 3, 2014

(30) Foreign Application Priority Data
Feb. 21, 2014 (KR) 10-2014-0020133

(51) Int. Cl. C23C 16/458; C23C 16/46

(52) U.S. Cl. CPC C23C 16/4586; C23C 16/46; C23C 16/4584; C23C 16/4585

(57) ABSTRACT

There is provided a susceptor. The susceptor includes: a body having a first surface, a second surface opposite the first surface, and an outer side surface connecting the first surface and the second surface; at least one pocket recessed from the first surface to accommodate at least one wafer therein, respectively; at least one tunnel respectively located below the pocket and extending from a center of the body to the outer side surface; at least one connecting channel each of which connects each of the pocket to each of the tunnel; and a supply line connected to the tunnel at the center of the body and supplying a gas from an outside in order for the gas to flow from the center of the body to the outer side surface.

### CROSS-REFERENCE TO RELATED APPLICATION

This application claims priority from Korean Patent Application No. 10-2014-0020133 filed on Feb. 21, 2014, with the Korean Intellectual Property Office, the disclosure of which is incorporated herein in its entirety by reference.

### BACKGROUND

Apparatuses consistent with exemplary embodiments of the inventive concept relate to a susceptor and a chemical vapor deposition (CVD) apparatus including the susceptor.

In general, a CVD apparatus is an apparatus for forming a nitride semiconductor layer on a wafer using a chemical reaction. The CVD apparatus supplies a reactant gas with a high vapor pressure to a heated wafer and grows a nitride semiconductor layer on the wafer using the reactant gas.

As the nitride semiconductor layer grows, bowing may occur between the wafer and the nitride semiconductor layer due to differences in lattice constants and thermal expansion coefficients between the wafer and the nitride semiconductor layer. Due to the bowing, a temperature imbalance may occur in a surface of the wafer, and accordingly a composition of the nitride semiconductor layer grown on the wafer may be non-uniform. As a result, non-uniformity in terms of thickness and wavelength may increase.

A semiconductor light emitting device including such a non-uniformly grown nitride semiconductor layer may have non-uniform emission wavelengths and electrical characteristics, resulting in poor quality, performance, and yield.

### SUMMARY

One or more exemplary embodiments provide a susceptor which may be able to minimize bowing of a wafer during a process of growing a nitride semiconductor layer on the wafer.

The technical objectives of the inventive concept are not limited to the above disclosure; other objectives may become apparent to those of ordinary skill in the art based on the following descriptions.

According to an aspect of an exemplary embodiment, there is provided a susceptor which may include: a body including a first surface, a second surface opposite the first surface, and an outer side surface connecting the first surface and the second surface; at least one pocket recessed from the first surface to accommodate at least one wafer therein, respectively; at least one tunnel respectively located below the pocket and extending from a center of the body to the outer side surface; at least one connecting channel each of which connects each of the pocket to each of the tunnel; and a supply line connected to the tunnel at the center of the body and supplying a gas from an outside in order for the gas to flow from the center of the body to the outer side surface.

The at least one pocket may include a plurality of pockets, and the at least one tunnel may include a plurality of tunnels corresponding to the plurality of pockets, respectively. Further, the at least one connecting channel may include a plurality of connecting channels connecting the plurality of pockets and the plurality of tunnels, respectively

The plurality of tunnels may extend radially from the center of the body to the outer side surface.

The plurality of tunnels may have a relatively small cross-sectional area at a portion connected to the plurality of connecting channels, respectively.

Each of the plurality of tunnels may extend from the center of the body to the outer side surface in a straight line.

Each of the plurality of tunnels may extend from the center of the body to the outer side surface in a curve.

The plurality of connecting channels may be connected to plurality of tunnels through bottom surfaces of the plurality of pockets, respectively, and each of the plurality of pockets may include one or more connecting channels connecting the pocket with a corresponding tunnel of the plurality of tunnels.

The susceptor may further include a plurality of secondary connecting channels each of which may pass through an inner side surface of a corresponding pocket of the plurality of pockets and connect the pocket and a corresponding tunnel of the plurality of tunnels.

A plurality of the secondary connecting channels may be arranged to be spaced apart from one another at regular intervals along the inner side surface of the pocket.

The susceptor may further include a center axle disposed on the second surface of the body.

The supply line may be disposed in the center axle of the body and extend perpendicularly along the center axle to be connected to the plurality of tunnels in the center of the body.

The gas may include an inert gas.

According to an aspect of another exemplary embodiment, there is provided a chemical vapor deposition (CVD) apparatus which may include a reaction chamber and the above susceptor disposed in the reaction chamber.

The CVD apparatus may further include a reactant gas supplying system supplying a reactant gas into the reaction chamber.

The CVD apparatus may further include a heating system heating a wafer disposed on the susceptor.

The CVD apparatus may further include a driving system rotating the susceptor.

### BRIEF DESCRIPTION OF DRAWINGS

The above and other aspects, features and other advantages of the inventive concept will be more clearly understood from the following detailed description of the exemplary embodiments taken in conjunction with the accompanying drawings, in which:

FIG. 1 is a cross-sectional view schematically illustrating a susceptor, according to an exemplary embodiment;

FIG. 2 is a plan view schematically illustrating the susceptor of FIG. 1, according to an exemplary embodiment;

FIG. 3 is a partial perspective view schematically illustrating structures of a pocket, a connecting channel, and a tunnel in the susceptor of FIG. 1, according to an exemplary embodiment;

FIGS. 4A and 4B are cross-sectional views schematically illustrating how to minimize bowing of a wafer, according to an exemplary embodiment;

FIG. 5 is a cross-sectional view schematically illustrating a susceptor, according to another exemplary embodiment;

FIG. 6 is a plan view schematically illustrating a susceptor according to another exemplary embodiment;

FIG. 7A is a cross-sectional view schematically illustrating a susceptor according to another exemplary embodiment;

FIG. 7B is a plan view schematically illustrating a pocket of FIG. 7A, according to an exemplary embodiment;

FIG. 8 is a cross-sectional view schematically illustrating a susceptor, according to another exemplary embodiment;

FIG. 9 is a partial perspective view schematically illustrating structures of a pocket, a connecting channel, a tunnel, and a secondary connecting channel in the susceptor of FIG. 8, according to an exemplary embodiment;

FIG. 10A is a cut perspective view schematically illustrating the structures of the pocket, the connecting channel, the tunnel, and the secondary connecting channel in the susceptor of FIG. 9, according to an exemplary embodiment;

FIG. 10B is a plan view schematically illustrating the pocket of FIG. 10A, according to an exemplary embodiment;

FIG. 11 is a cross-sectional view schematically illustrating a chemical vapor deposition (CVD) apparatus according to an exemplary embodiment; and

FIG. 12 is a cross-sectional view schematically illustrating a state in which the CVD apparatus of FIG. 11 is open, according to an exemplary embodiment.

### DETAILED DESCRIPTION OF EXEMPLARY EMBODIMENTS

Exemplary embodiments of the inventive concept will now be described in detail with reference to the accompanying drawings. The disclosure may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art. In the drawings, the shapes and dimensions of elements may be exaggerated for clarity, and the same reference numerals will be used throughout to designate the same or like elements.

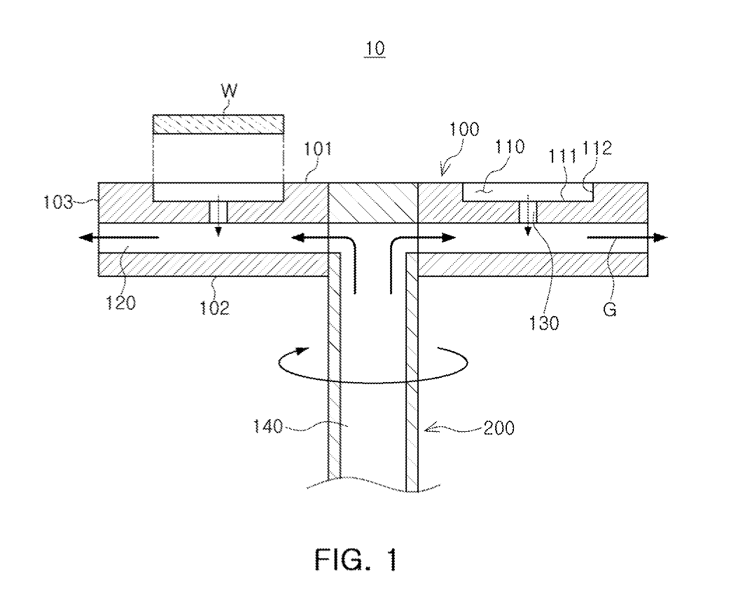

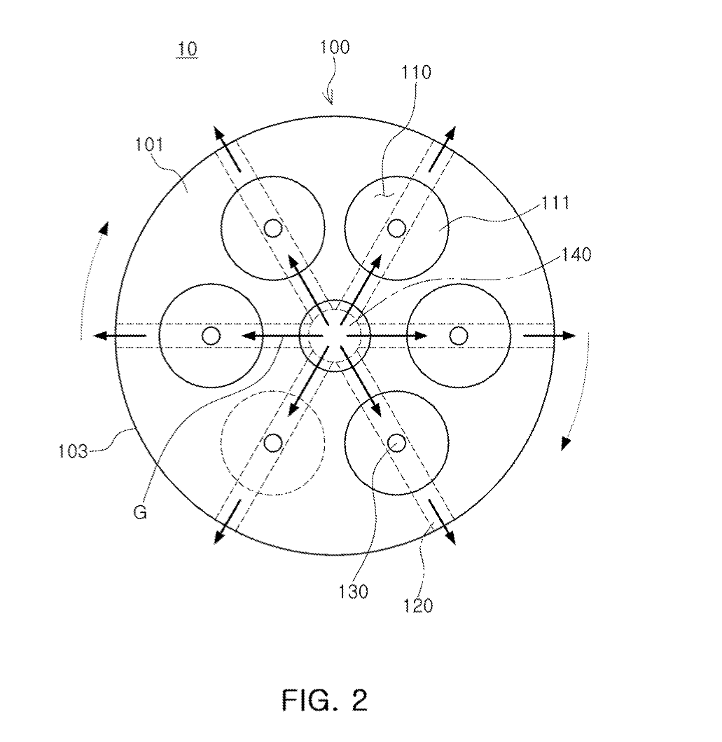

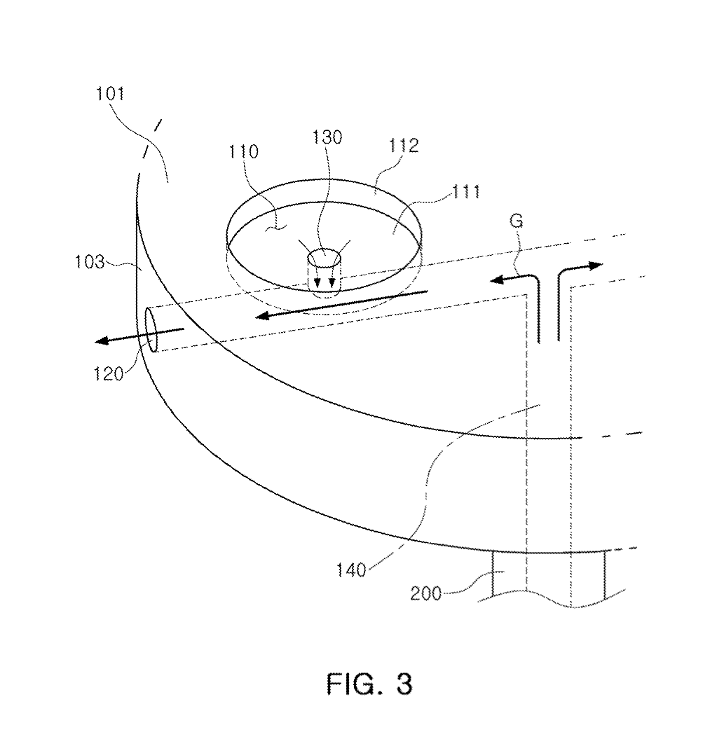

A susceptor according to an exemplary embodiment of the present disclosure will be described with reference to FIGS. 1 to 3. FIG. 1 is a cross-sectional view schematically illustrating a susceptor according to an exemplary embodiment, FIG. 2 is a plan view schematically illustrating the susceptor of FIG. 1, and FIG. 3 is a partial perspective view schematically illustrating structures of a pocket, a connecting channel, and a tunnel in the susceptor of FIG. 1.

Referring to FIGS. 1 to 3, a susceptor 10 according to the exemplary embodiment may include a body 100 that has a first surface 101, a second surface 102 opposite to the first surface 101, and an outer side surface 103 connecting the first surface 101 and the second surface 102. The susceptor 10 may further include a center axle 200 protruded from the second surface 102 of the body 100.

The body 100 may have a shape of a circular disk which includes the first surface 101 and second surface 102 substantially in parallel, and the outer side surface 103 extending perpendicularly from circumferences of the first surface 101 and the second surface 102 to be connected. The first surface 101 and the second surface 102 may define an upper surface and a lower surface of the body 100, respectively, and have the same area in size.

The body 100 has the circular disk shape in this exemplary embodiment, but is not limited thereto. For example, the body 100 may have the shape of a tetragonal or polygonal disk instead of the circular disk shape.

The body 100 may be formed of a material having a superior thermal resistance because the body 100 is exposed to a high temperature environment. As a material of the body 100, for example, quartz, graphite, graphite coated with SiC, or the like may be included. However, the material of the body 100 is not limited thereto.

The center axle 200 may be disposed in the center of the second surface 102 of the body 100. The center axle 200 may have a structure linked to the body 100 through the second surface 102 of the body 100. In addition, the center axle 200 may be integrated with the body 100.

The center axle 200 may support the body 100 in a fixed state. In addition, the center axle 200 may rotate the body 100 in a predetermined direction.

The first surface 101 of the body 100 may include a plurality of pockets 110 recessed to a predetermined depth. A wafer W may be disposed in the pocket 110.

The plurality of pockets 110 may have a shape corresponding to the wafer W disposed therein. In addition, the plurality of pockets 110 may have a depth corresponding to a thickness of the wafer W in such a way that an exposed upper surface of the wafer W disposed therein may be substantially parallel to the first surface 101 which defines the upper surface of the body 100.

Shapes and sizes of the plurality of pockets 110 may be variously modified to correspond to shapes and sizes of the wafer W. In addition, the number of the pockets 110 may be variously changed.

The body 100 may include a plurality of tunnels 120 disposed between the first surface 101 and the second surface 102 and extending substantially parallel to the first surface 101 and the second surface 102 along the inside of the body 100.

The plurality of tunnels 120 may be respectively disposed below the plurality of pockets 110, and extend to pass through the center of the body 100 and to be connected to the outer side surface 103. The plurality of tunnels 120 may correspond numerically and in terms of positions thereof to the plurality of pockets 110. Further, the plurality of tunnels 120 may have one ends connected to each other at the center of the body 100, and the other ends exposed to the outside through the outer side surface 103 of the body 100.

As illustrated in FIG. 2, when viewed from above the body 100, the plurality of tunnels 120 may be formed and arranged to have a structure extending radially from the center of the body 100 toward the outer side surface 103. In addition, the plurality of tunnels 120 may extend linearly.

In this exemplary embodiment, the tunnel 120 extends parallel to the first surface 101 and the second surface 102 within the body 100, but is not limited thereto. For example, the tunnel 120 may have a structure inclined with a predetermined slope and extend from the center of the body 100 toward the outer side surface 103.

The plurality of tunnels 120 may be connected to a supply line 140 that will be described later, at the center of the body 100.

The body 100 may include a connecting channel 130 connecting the plurality of pockets 110 and the plurality of tunnels 120, respectively. The connecting channel 130 may pass through a bottom surface 111 of a corresponding pocket 110 to be connected to the tunnel 120 located below the corresponding pocket 110.

The connecting channel 130 may have a cross-sectional area corresponding to that of the tunnel 120. In addition, the connecting channel 130 may have a different cross-sectional area from the tunnel 120. For example, the connecting channel 130 may have a smaller cross-sectional area than the tunnel 120.

In this exemplary embodiment, the connecting channel 130 extends perpendicular to the bottom surface 111 of the pocket 110, but is not limited thereto. For example, the connecting channel 130 may have an inclined structure and extend from the bottom surface 111 of the pocket 110 to the tunnel 120.

Meanwhile, the body 100 may include the supply line 140 connected to the plurality of tunnels 120 and supplying gas G from the outside to the plurality of tunnels 120.

The supply line 140 may be located inside the center axle 200 and vertically extend along the center axle 200. In addition, the supply line 140 may be connected to the plurality of tunnels 120 at the center of the body 100.

The supply line 140 may extend to the outside along the center axle 200. For example, the supply line 140 may be connected to a reservoir (not shown) filled with the gas G. The gas G may include an inert gas, such as hydrogen (H₂) and nitrogen (N₂), but is not limited thereto.

The supply line 140 supplies the gas G, for example, an inert gas from the outside to the plurality of tunnels 120 in such a way that the gas G flows from the center of the body 100 toward the outer side surface 103 along the plurality of tunnels 120.

In addition, the gas G flows from the center of the body 100 toward the outer side surface 103 along the plurality of tunnels 120 and is then discharged to the outside. In this case, the gas G needs to pass through the tunnel 120 to be discharged to the outside at a relatively high speed. That is, a flow at high speed needs to be formed in the tunnel 120. For this, the gas G may be forced to flow into the supply line 140, for example, through a pump, and injected into the plurality of tunnels 120.

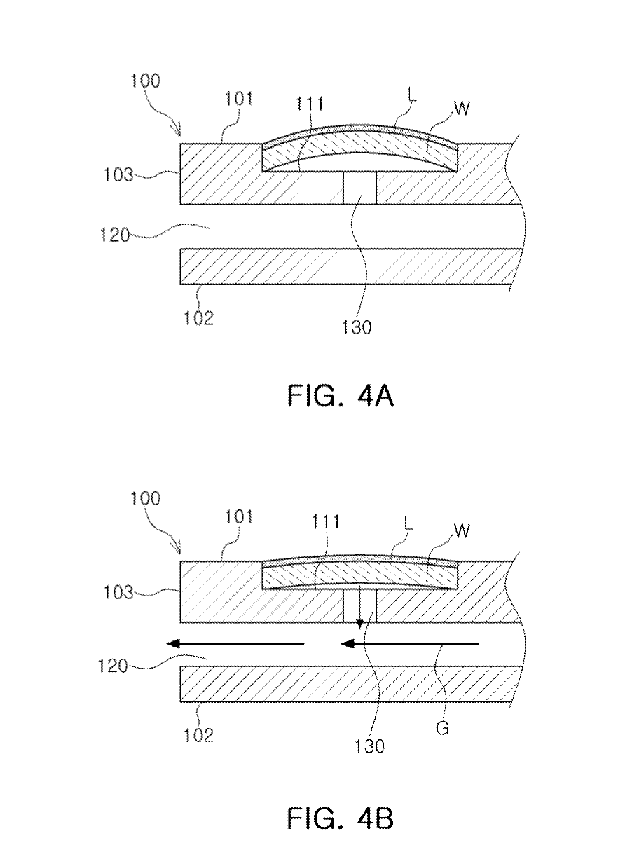

FIGS. 4A and 4B schematically illustrate how to minimize bowing of a wafer.

The gas G flowing through the tunnel 120 may form a flow at a speed enough to generate a pressure difference between the tunnel 120 and the connecting channel 130, specifically, the connecting channel 130 and the pocket 110 connected thereto. That is, when the gas G flows along the tunnel 120 at a high speed to be discharged to the outside, a pressure difference between the tunnel 120 and the pocket 110 may be generated due to the Bernoulli Effect. At this time, since a pressure in the tunnel 120 becomes relatively low, air in the pocket 110 flows into the tunnel 120 through the connecting channel 130, and the wafer W disposed in the pocket 110 tightly adheres to the bottom surface 111 of the pocket 110 due to a suction force according to inflow of the air.

The suction force is applied in a direction opposite to a direction in which the wafer W is bent. Accordingly, the bowing is eased since a stress is applied to the wafer W in the direction opposite to the direction of the bowing.

The wafer W and a nitride semiconductor layer L will be described in detail. The wafer W may be used as a growth substrate for growing a nitride semiconductor layer L, and a sapphire substrate, for example, may be used. The sapphire substrate is a crystal having Hexa-Rhombo (R3c) symmetry, and has lattice constants of 13.001 Å and 4.758 Å respectively along c-axis and a-axis, and the C-plane (0001), the A-plane (1120), and the R-plane (1102). In this case, since the C-plane allows a nitride thin film to be relatively easily grown thereupon and is stable even at high temperatures, the C-plane sapphire substrate is predominantly utilized as a substrate for growing a nitride semiconductor. However, a substrate formed of Si, SiC, GaN, ZnO, MgAl₂O₄, MgO, LiAlO₂, or LiGaO₂ may be used.

As described above, bowing of the wafer W may occur during a process of growing the nitride semiconductor layer L, and in particular, the effect of the bowing increases more when the wafer W has a large diameter, e.g. two (2) inches or more.

An example of the nitride semiconductor layer L may be a material represented by an empirical formula AlₓIn_{y}Ga_{(1-x-y)}N, where 0≦x≦1, 0≦y≦1, and 0≦x+y≦1. The nitride semiconductor layer L may be grown using a metalorganic chemical vapor deposition (MOCVD) process, a hydride vapor phase epitaxy (HYPE) process, an atomic layer deposition (ALD) process, or the like. In this case, since the nitride semiconductor layer L has a smaller lattice constant than the wafer W formed of sapphire, or the like, bowing caused by a tensile stress may occur during the growth process.

According to the exemplary embodiment, a physical method may be used to minimize bowing of the wafer W and the nitride semiconductor layer L. That is, a space may be formed between the wafer W and the bottom surface 111 of the pocket 110 due to bowing occurring in the process of growing the nitride semiconductor layer L, and the bowing is eased in such a way that the wafer W sticks to the bottom surface 111 of the pocket 110 by the suction of air existing in the space.

Meanwhile, the process of easing the bowing using suction according to the exemplary embodiment may be continuously performed during the process of growing the nitride semiconductor layer L, or only during a part of time or a part of the process, as needed.

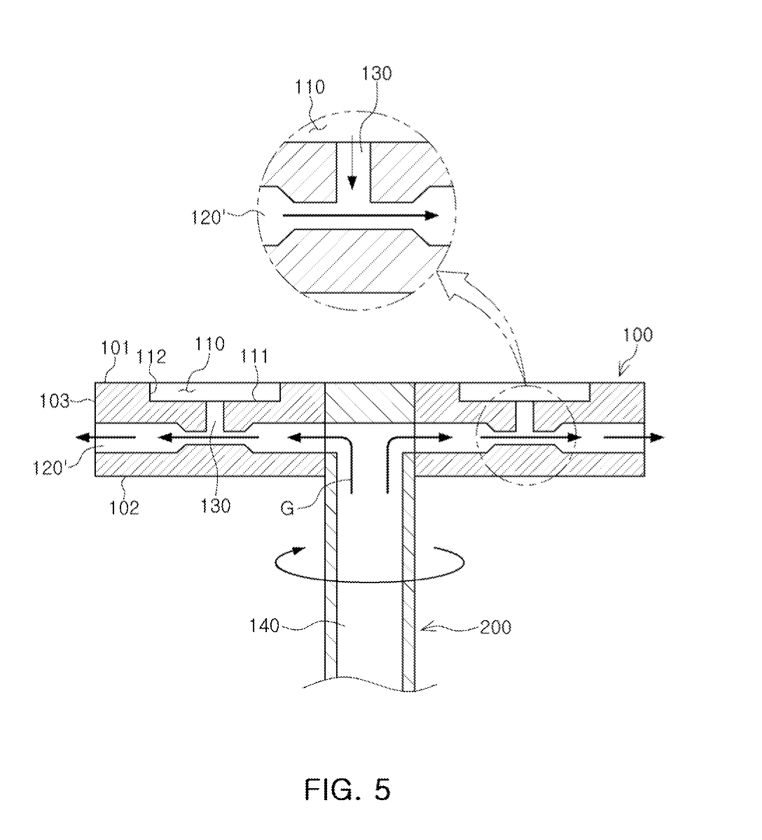

FIG. 5 schematically illustrates a susceptor according to another exemplary embodiment. FIG. 5 is a cross-sectional view schematically illustrating the susceptor according to the other exemplary embodiment.

A basic configuration of the susceptor described in FIG. 5 is substantially the same as described in FIG. 1, except that a structure of a tunnel is different from that described in FIG. 1. Therefore, duplicated descriptions of the above-described embodiment will be omitted herein, and a configuration of the tunnel will be mainly described.

As illustrated in FIG. 5, a plurality of tunnels 120′ may have a structure in which the size of a cross-sectional area is not uniform and changes. The plurality of tunnels 120′ may have a relatively small cross-sectional area at some parts connected to the connecting channel 130. The plurality of tunnels 120′ may have a structure such as a Venturi tube.

Accordingly, since a pressure in the tunnel 120′ drops at a part connected to the connecting channel 130, suction force acting on the connecting channel 130 toward the tunnel 120′ may increase. The increase of the suction force makes the air in the pocket 110 connected to the connecting channel 130 more strongly suctioned. Thus, the wafer W disposed in the pocket 110 is attracted as if being vacuum-suctioned, and attached on the bottom surface 111 of the pocket 110. Therefore, bowing of the wafer W can be eased.

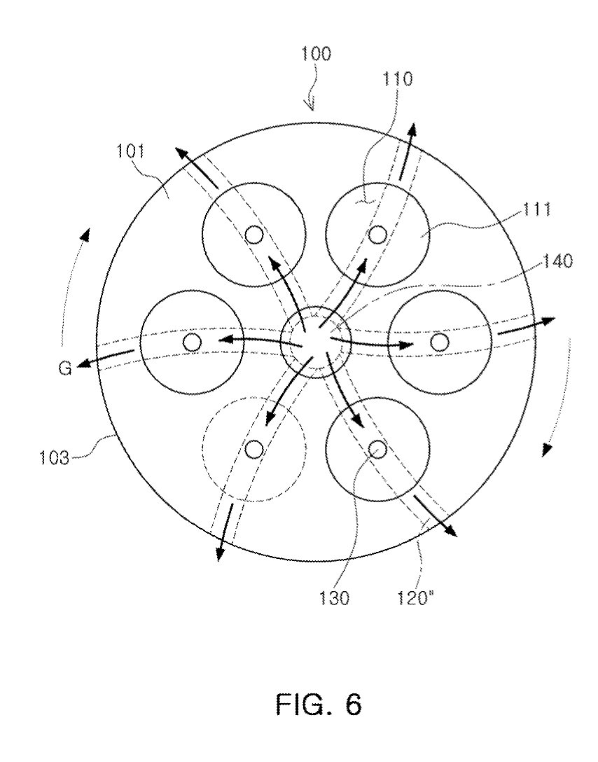

FIG. 6 schematically illustrates a susceptor according to another exemplary embodiment. FIG. 6 is a plan view schematically illustrating the susceptor according to the other exemplary embodiment.

A basic configuration of the susceptor according to the exemplary embodiment described in FIG. 6 is substantially the same as described in FIGS. 1 and 5, except that a structure of a tunnel is different from those described in FIGS. 1 and 5. Therefore, duplicated descriptions of the above-described embodiment will be omitted herein, and a configuration of the tunnel will be mainly described.

As illustrated in FIG. 6, a plurality of tunnels 120″ may extend in a curve. That is, the plurality of tunnels 120″ extend in a curve from the center of the body 100 toward the outer side surface 103, unlike the tunnel extending in a straight line in FIGS. 1 and 5. In this case, the plurality of tunnels 120″ may have a structure curved in a direction corresponding to, when the body 100 rotates, the direction of rotation.

When the plurality of tunnels 120″ have the structure curved in the direction corresponding to the direction of rotation of the body 100, a flow rate of a gas G flowing to the outside passing through the tunnel 120″ while the body 100 rotates may increase. In addition, as the flow rate of the gas G flowing through the tunnel 120″ increases, suction force acting on the connecting channel 130 may increase. Accordingly, bowing of the wafer W disposed in the pocket 110 can be reduced.

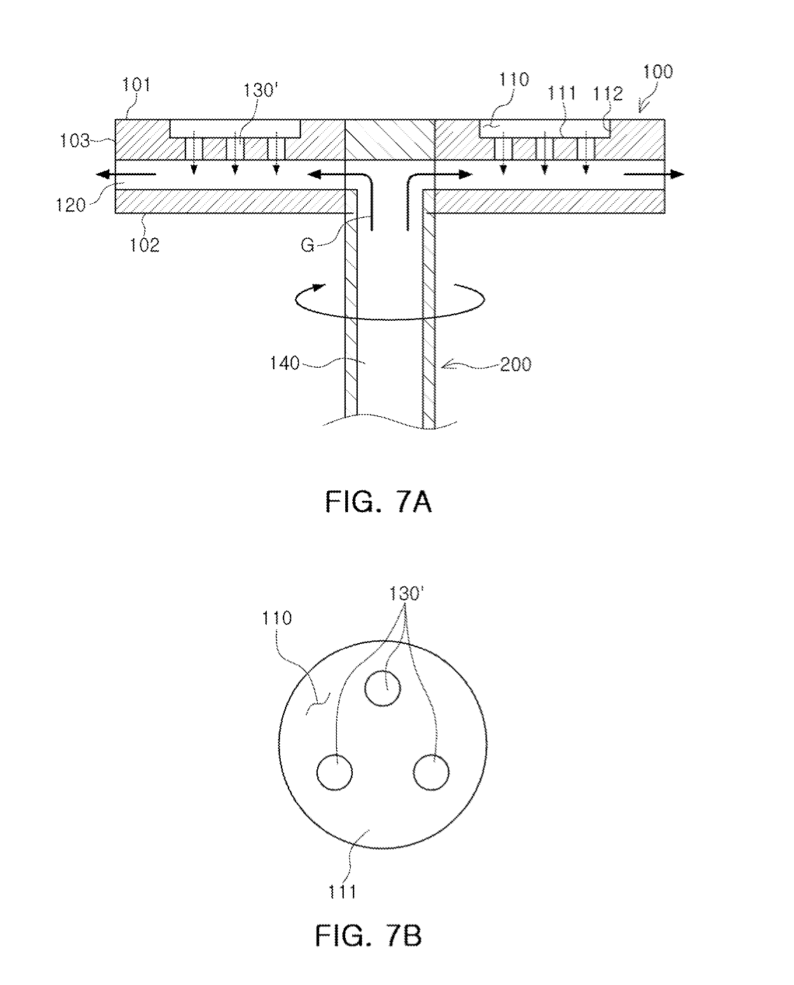

FIGS. 7A and 7B schematically illustrate a susceptor according to another exemplary embodiment. FIG. 7A is a cross-sectional view schematically illustrating the susceptor according to the other exemplary embodiment, and FIG. 7B is a plan view schematically illustrating a pocket of FIG. 7A.

A basic configuration of the susceptor according to the exemplary embodiment described in FIGS. 7A and 7B is substantially the same as described in FIG. 1, except that a structure of a connecting channel is different from that described in FIG. 1. Therefore, duplicated descriptions of the above-described embodiment will be omitted herein, and a configuration of the connecting channel will be mainly described.

As illustrated in FIGS. 7A and 7B, a susceptor 10 according to the exemplary embodiment includes a plurality of connecting channels 130′ passing through a bottom surface 111 of the pocket 110 and connected to each tunnel 120 located below the pocket 110. That is, there is a difference in that each pocket 110 has a plurality of the connecting channels 130′ in this exemplary embodiment, whereas each pocket 110 has a single connecting channel 130 in the exemplary embodiment of FIG. 1.

The plurality of connecting channels 130′ may be symmetrically arranged with respect to a center of the bottom surface 111 of the pocket 110. Although three connecting channels 130′ are included in this exemplary embodiment, the number of the connecting channels 130′ may be variously modified.

Since the plurality of connecting channels 130′ through which air is suctioned are widely distributed in the bottom surface 111 of the pocket 110, the suction force applied on the wafer W can widely and uniformly act on the entire wafer W. Accordingly, bowing of the wafer W can be eased.

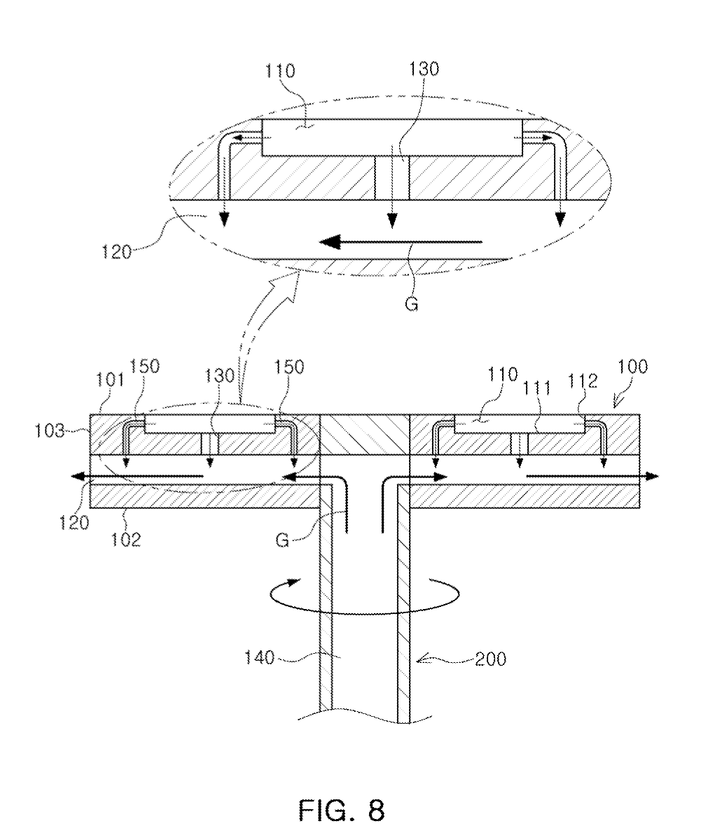

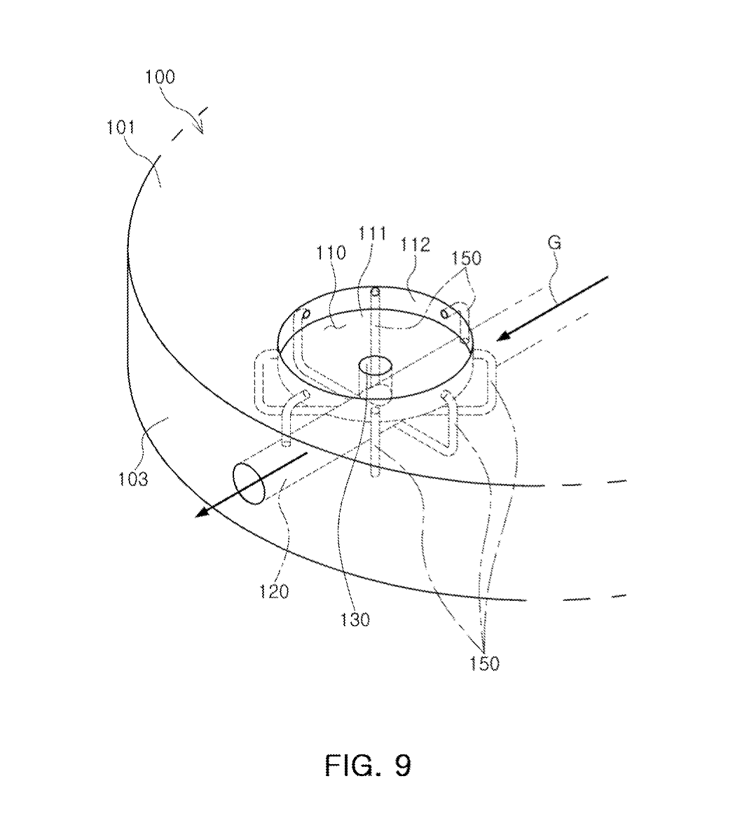

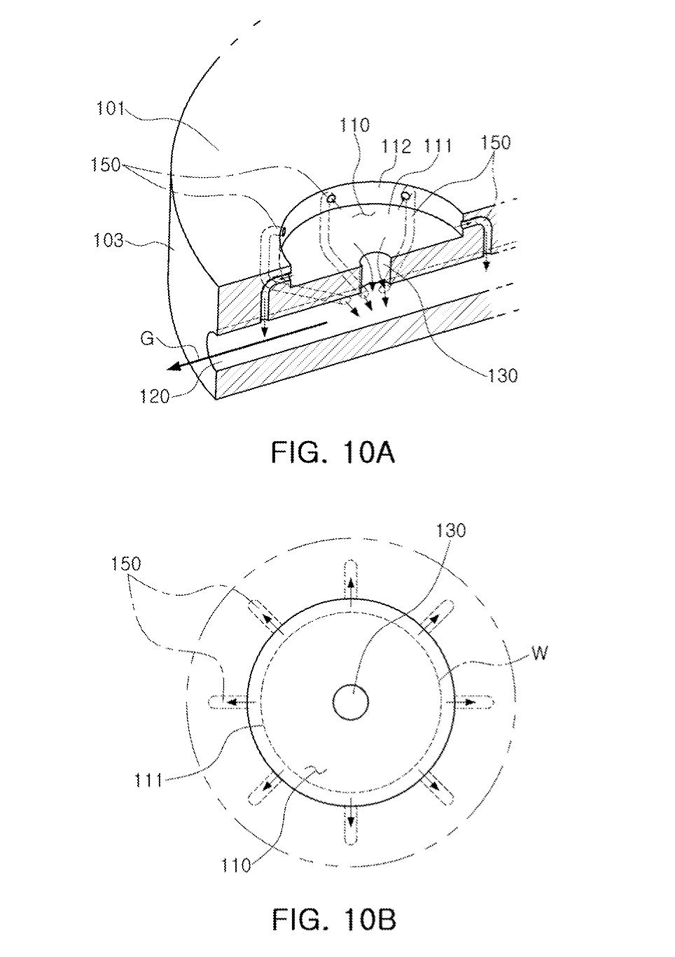

FIGS. 8 to 10 schematically illustrate a susceptor according to another exemplary embodiment. FIG. 8 is a cross-sectional view schematically illustrating the susceptor according to the other exemplary embodiment, and FIG. 9 is a partial perspective view schematically illustrating structures of a pocket, a connecting channel, a tunnel, and a secondary connecting channel in the susceptor of FIG. 8. FIG. 10A is a cut perspective view schematically illustrating the structures of the pocket, the connecting channel, the tunnel, and the secondary connecting channel in the susceptor of FIG. 9, and FIG. 10B is a plan view schematically illustrating the pocket of FIG. 10A.

A basic configuration of the susceptor according to the exemplary embodiment described in FIGS. 8 to 10 is substantially the same as described in FIG. 1, except that a structure of a connecting channel is different from those described in FIG. 1. Therefore, duplicated descriptions of the above-described embodiment will be omitted herein, and a configuration of the connecting channel will mainly be described.

As illustrated in FIGS. 8 to 10, a susceptor 10 according to the exemplary embodiment may further include a plurality of secondary connecting channels 150 passing through an inner side surface 112 of each pocket 110 and connecting the pocket 110 and the tunnel 120.

The plurality of secondary connecting channels 150 may be arranged to be spaced apart from one another at regular intervals along the inner side surface 112 of the pocket 110. In addition, the plurality of secondary connecting channels 150 may connect the pocket 110 and the tunnel 120 along with the connecting channel 130 passing though the bottom surface 111 of the pocket 110.

The plurality of secondary connecting channels 150 may surround a wafer W disposed in the pocket 110 so that the wafer W is disposed in a center area of the pocket 110 by suction force generated due to a pressure difference from the tunnel 120. That is, the wafer W can be disposed in the center area due to the suction force applied along a circumference of the wafer W, without being displaced in a certain direction in the pocket 110.

In a related art, a wafer may be not located in a center area in a pocket but displaced in a certain direction due to a centrifugal force generated during rotation of a susceptor. Accordingly, the wafer may be partly in direct contact with an inner side surface of the pocket. In this case, a part in direct contact with the pocket is heated to a high temperature, and a temperature distribution across the wafer may be not uniform. In addition, the non-uniform temperature distribution may cause thickness and wave length characteristics of a semiconductor layer to be non-uniform.

According to the exemplary embodiment, since the plurality of secondary connecting channels 150 are disposed along the circumference of the wafer W, the suction force applied to the wafer W uniformly acts in all directions, and displacement of the wafer W can be prevented. Accordingly, uniform temperature distribution can be maintained.

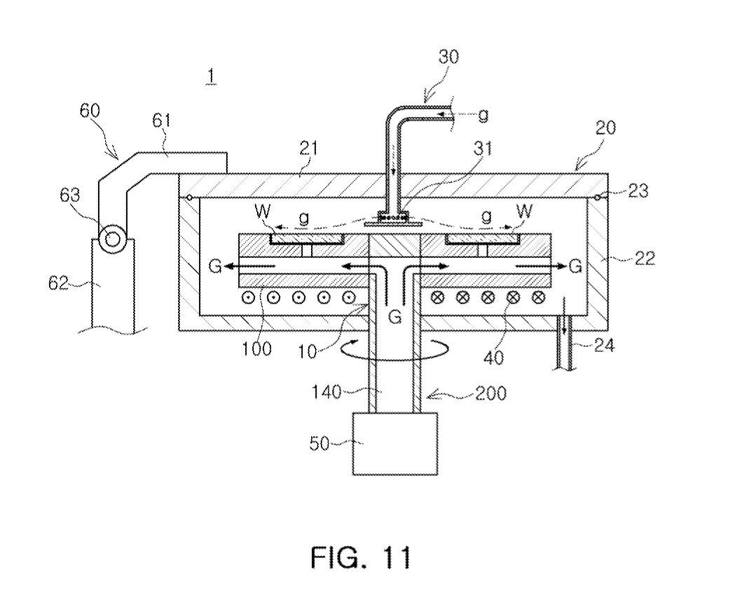

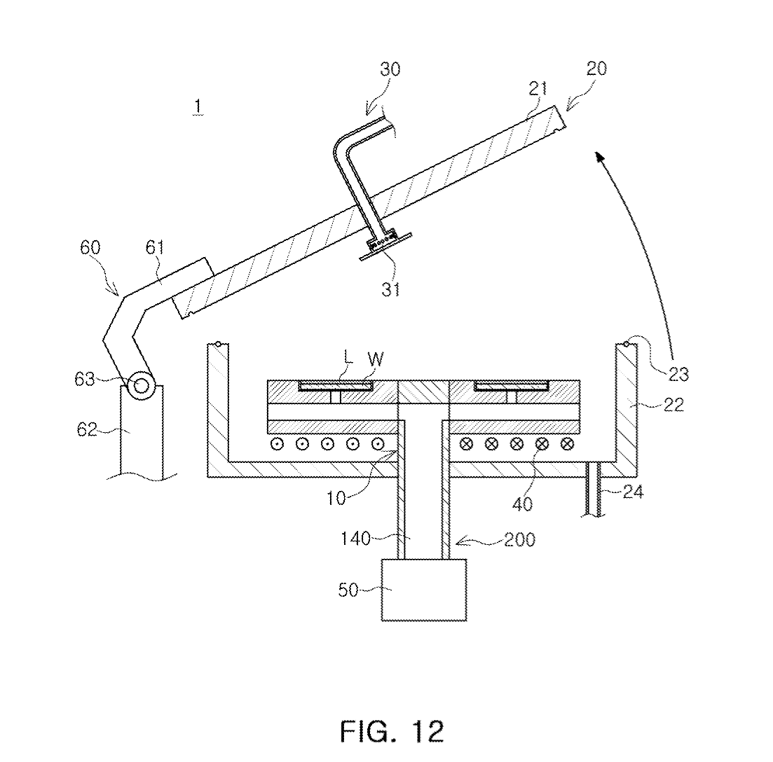

A chemical vapor deposition (CVD) apparatus according to an exemplary embodiment will be described with reference to FIGS. 11 and 12. FIG. 11 is a cross-sectional view schematically illustrating the CVD apparatus according to the exemplary embodiment, and FIG. 12 is a cross-sectional view schematically illustrating a state in which the CVD apparatus of FIG. 11 is open.

Referring to FIGS. 11 and 12, a CVD apparatus 1 according to the exemplary embodiment may include a reaction chamber 20 and a susceptor 10 disposed in the reaction chamber 20. In addition, the CVD apparatus 1 may further include a reactant gas supplying system 30 supplying a reactant gas g into the reaction chamber 20.

The reaction chamber 20 may include a chamber body 22 having an inner space having a certain size, and a chamber cover 21 sealing the chamber body 22 to maintain an airtight state. In addition, the chamber body 22 may be opened and closed by the chamber cover 21.

A sealing part 23 such as an o-ring may be disposed on an upper end of the chamber body 22 combining with the chamber cover 21 in order to ensure air-tightness. The reaction chamber 20 may be formed of a material having excellent wear resistance and corrosion resistance, for example, a metal material.

A cover pivoting system 60 may be disposed in a side of the reaction chamber 20. The cover pivoting system 60 may pivot the chamber body 22 or the chamber cover 21 to separate or combine the chamber body 22 and the chamber cover 21. The cover pivoting system 60 may include a pivoting arm 61 having an end connected to the chamber cover 21, and a fixed arm 62 having an upper end is connected to the pivoting arm 61 mediated by a hinge axle 63.

According to the exemplary embodiment, the pivoting arm 61 is connected to the chamber cover 21 and pivots the chamber cover 21 with respect to the chamber body 22 to perform a combination or separation operation of the chamber body 22 and the chamber cover 21, but is not limited thereto.

The susceptor 10 may be disposed in the reaction chamber 20, and fixed and supported by a center axle 200 located in the center of the chamber body 22.

In addition, the susceptor 10 may be rotatable. In this case, the center axle 200 may be connected to a body 100 of the susceptor 10 on a side, and a driving system 50 on the other side. In addition, the center axle 200 may rotate the body 100 by an operation of the driving system 50. The driving system 50 may use various well-known devices generating a rotating force, for example, a rotary motor.

The susceptor 10 is the same as the susceptor 10 described in FIGS. 1 to 10, and detailed descriptions thereof will be omitted.

A heating system 40 may be disposed below the susceptor 10. The heating system 40 may provide radiant heat to the susceptor 10, and thereby a wafer W mounted on the susceptor 10 may be heated.

The heating system 40 may use various well-known devices generating heat to heat the wafer W, for example, a heat transfer member generating heat when electric power is applied. In addition, the heating system 40 may be disposed at an area corresponding to a pocket 110.

The reactant gas supplying system 30 supplies the reactant gas g to the reaction chamber 20 so that the reactant gas g flows between the susceptor 10 and the chamber cover 21 which are facing each other. More specifically, the reactant gas supplying system 30 may be disposed in the center of the chamber cover 21 to form a flow of the reactant gas g from the center of the reaction to chamber 20 toward an outer circumference.

The reactant gas supplying system 30 may include a gas supply line passing through the center of the chamber cover 21 and extending into the reaction chamber 20, and a spray nozzle 31 spraying the reactant gas g at the end of the gas supply line.

The reactant gas g flowing into the reaction chamber 20 through the reactant gas supplying system 30 may flow from the center of the reaction chamber 20 toward the outer circumference along a surface of the susceptor 10, and may be discharged to the outside through an exhaust unit 24 disposed at a lower portion of the reaction chamber 20.

As the reactant gas g, trimethyl gallium (TMGa), triethyl gallium (TEGa), trimethyl aluminum (TMAl), trimethyl indium (TMIn), NH₃, or the like may be used.

As set forth above, according to the exemplary embodiments, a susceptor and a CVD apparatus including the susceptor may be provided. The susceptor may minimize bowing of a wafer when a nitride semiconductor layer is grown on the wafer.

While exemplary embodiments have been shown and described above, it will be apparent to those skilled in the art that modifications and variations could be made without departing from the spirit and scope of the inventive concept as defined by the appended claims.

What is claimed is:

1. A susceptor comprising:
a body including a first surface, a second surface opposite the first surface, and an outer side surface connecting the first surface and the second surface;
at least one pocket recessed from the first surface to accommodate at least one wafer therein, respectively;
at least one tunnel respectively located below the pocket and extending from a center of the body to the outer side surface;
at least one connecting channel each of which connects each of the pocket to each of the tunnel; and
a supply line connected to the tunnel at the center of the body and supplying a gas from an outside in order for the gas to flow from the center of the body to the outer side surface.

2. The susceptor of claim 1, further comprising an axle connected to the body and configured to rotate the body,
wherein the supply line is configured to supply the gas from the outside into the tunnel during rotation of the body.

3. The susceptor of claim 1, wherein a cross-sectional area of the connecting channel is smaller than a cross-sectional area of the tunnel.

4. The susceptor of claim 1, wherein the tunnel has a relatively small cross-sectional area at a portion connected to the connecting channel.

5. The susceptor of claim 1, wherein the tunnel has a relatively smaller cross-sectional area at a portion connected to the connecting channel.

6. The susceptor of claim 1, wherein the tunnel extends from the center of the body to the outer side surface in a curve.

7. The susceptor of claim 1, wherein the at least one pocket comprises a plurality of pockets, and the at least one tunnel comprises a plurality of tunnels corresponding to the plurality of pockets, respectively, and
wherein the at least one connecting channel comprises a plurality of connecting channels connecting the plurality of pockets and the plurality of tunnels, respectively.

8. The susceptor of claim 7, wherein the plurality of tunnels extend radially from the center of the body to the outer side surface.

9. The susceptor of claim 7, wherein the plurality of tunnels have a relatively small cross-sectional area at a portion connected to the plurality of connecting channels, respectively.

10. The susceptor of claim 7, wherein each of the plurality of tunnels extends from the center of the body to the outer side surface in a straight line.

11. The susceptor of claim 7, wherein each of the plurality of tunnels extends from the center of the body to the outer side surface in a curve.

12. The susceptor of claim 7, wherein the plurality of connecting channels are connected to the plurality of tunnels through bottom surfaces of the plurality of pockets, respectively, and
wherein each of the plurality of pockets includes one or more connecting channels connecting the pocket with a corresponding tunnel of the plurality of tunnels.

13. The susceptor of claim 7, further comprising a plurality of secondary connecting channels each of which passes through an inner side surface of a corresponding pocket of the plurality of pockets and connects the pocket and a corresponding tunnel of the plurality of tunnels.

14. The susceptor of claim 13, wherein a plurality of the secondary connecting channels are arranged to be spaced apart from one another at regular intervals along the inner side surface of the pocket.

15. The susceptor of claim 7, further comprising a center axle protruded from the second surface of the body.

16. The susceptor of claim 15, wherein the supply line is disposed in the center axle of the body and extends along the center axle to be connected to the plurality of tunnels in the center of the body.

17. A chemical vapor deposition (CVD) apparatus comprising:
a reaction chamber; and
a susceptor disposed in the reaction chamber,
wherein the susceptor includes:
a body including a first surface, a second surface opposite the first surface, and an outer side surface connecting the first surface and the second surface;
at least one pocket recessed from the first surface to accommodate at least one wafer therein, respectively;
at least one tunnel respectively located below the pocket and extending from a center of the body to the outer side surface;
at least one connecting channel each of which connects each of the pocket to each of the tunnel; and
a supply line connected to the tunnel at the center of the body and supplying a gas from an outside in order for the gas to flow from the center of the body to the outer side surface.

18. The CVD apparatus of claim 17, further comprising a reactant gas supplying system supplying a reactant gas into the reaction chamber.

19. The CVD apparatus of claim 17, further comprising a heating system heating a wafer disposed in the susceptor.

20. The CVD apparatus of claim 17, further comprising a driving system rotating the susceptor.
